(19) United States
(12) Patent Application Publication
(10) Pub. No.: US 2008/0159155 A1
(43) Pub. Date: Jul. 3, 2008

(54) METHOD AND APPARATUS FOR PROVIDING TROUBLE ISOLATION FOR A PERMANENT VIRTUAL CIRCUIT

(76) Inventors: Paritosh Bajpay, Edison, NJ (US); Monowar Hossain, Middletown, NJ (US); Mark Hunt, Plano, TX (US); Wen-Jui Li, Bridgewater, NJ (US); Chen-Yui Yang, Marlboro, NJ (US)

Correspondence Address: AT&T CORP., ROOM 2A207, ONE AT&T WAY, BEDMINSTER, NJ, 07921, US

(21) Appl. No.: 11/618,909

(22) Filed: Jan. 1, 2007

(51) Int. Cl. G01R 31/08

(52) U.S. Cl. 370/248

(57) ABSTRACT

A method and apparatus for providing trouble isolation for a Permanent Virtual Circuit (PVC) on packet networks are disclosed. For example, the method receives an alert or a ticket for a Permanent Virtual Circuit (PVC) down or a PVC degraded and starts a correlation window for said PVC and port alert or ticket. The method then gathers a plurality of port and PVC alerts for a duration of said correlation window and determines whether or not a port down or a port degraded alert is received along with a PVC down or a PVC degraded alert in said correlation window for one or more ports associated with said PVC.

The present invention relates generally to communication networks and, more particularly, to a method and apparatus for providing trouble isolation for a permanent virtual circuit on networks such as the packet networks, e.g. Internet Protocol (IP) networks, Asynchronous Transfer Mode (ATM) networks, Frame Relay (FR) networks, etc.

### BACKGROUND OF THE INVENTION

An enterprise customer may build a Virtual Private Network (VPN) by connecting multiple sites or users over a network from a telephony service provider. The enterprise VPN and customer premise equipment such as Customer Edge Routers (CER) may be managed by the network service provider. When the network service provider manages the VPNs and CERs, the CERs are connected to the network service provider's Layer 2 network through a Provider Edge Router (PER). The Layer 2 network is typically an Asynchronous Transfer Mode (ATM) and/or Frame Relay (FR) network. The voice and data packets from the customer premise may traverse the Layer 2 network prior to reaching an IP network. For example, a Permanent Virtual Circuit (PVC) may be established for the customer through a Layer 2 network, e.g. an ATM network. However, when a customer or a monitoring system reports trouble for a PVC, the service provider may not be able to determine whether or not the reported trouble is due to a port failure/degradation or a PVC failure/degradation. Improper isolation increases the time and cost associated with handling the trouble. A ticket opened for a customer trouble may be inappropriately closed after testing a non-failed network segment. Trouble escalation and manual intervention add tremendous cost for maintenance of a network.

Therefore, there is a need for a method that provides trouble isolation for permanent virtual circuits.

### SUMMARY OF THE INVENTION

In one embodiment, the present invention discloses a method and apparatus for providing trouble isolation for a Permanent Virtual Circuit (PVC) on packet networks. For example, the method receives an alert or a ticket for a Permanent Virtual Circuit (PVC) down or a PVC degraded and starts a correlation window for said PVC and port alert or ticket. The method then gathers a plurality of port and PVC alerts for a duration of said correlation window and determines whether or not a port down or a port degraded alert is received along with a PVC down or a PVC degraded alert in said correlation window for one or more ports associated with said PVC.

### BRIEF DESCRIPTION OF THE DRAWINGS

The teaching of the present invention can be readily understood by considering the following detailed description in conjunction with the accompanying drawings, in which:

FIG. 1 illustrates an exemplary network related to the present invention;

FIG. 2 illustrates an exemplary network for providing trouble isolation for a Permanent Virtual Circuit (PVC);

FIG. 3 illustrates a flowchart of a method for providing trouble isolation for a Permanent Virtual Circuit (PVC); and

FIG. 4 illustrates a high-level block diagram of a general-purpose computer suitable for use in performing the functions described herein.

To facilitate understanding, identical reference numerals have been used, where possible, to designate identical elements that are common to the figures.

### DETAILED DESCRIPTION

The present invention broadly discloses a method and apparatus for providing trouble isolation for a Permanent Virtual Circuit (PVC). Although the present invention is discussed below in the context of packet networks, the present invention is not so limited. Namely, the present invention can be applied for other networks, e.g. Public Switched Telephone Network (PSTN).

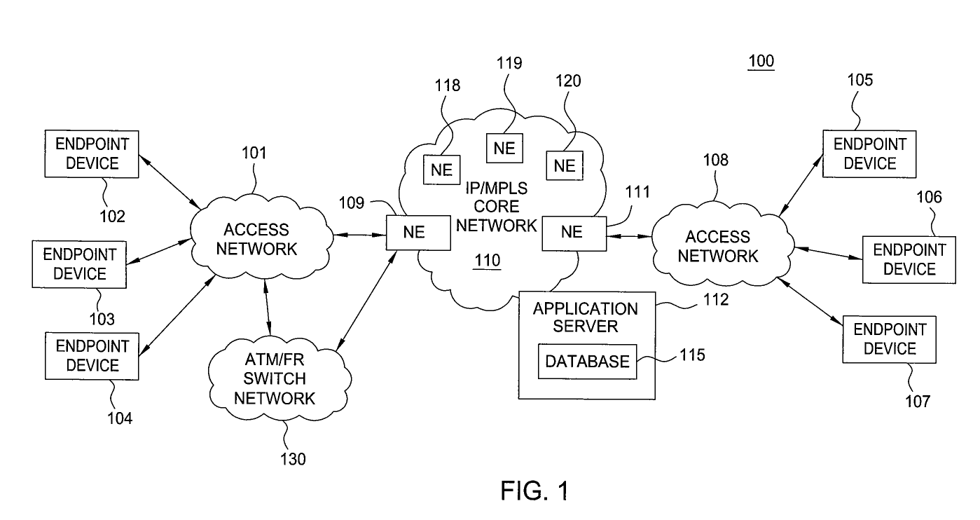

FIG. 1 is a block diagram depicting an exemplary packet network 100 related to the current invention. Exemplary packet networks include Internet protocol (IP) networks, Asynchronous Transfer Mode (ATM) networks, frame-relay networks, and the like. An IP network is broadly defined as a network that uses Internet Protocol such as IPv4 or IPv6 to exchange data packets.

In one embodiment, the packet network may comprise a plurality of endpoint devices 102-104 configured for communication with the core packet network 110 (e.g., an IP based core backbone network supported by a service provider) via an access network 101. Similarly, a plurality of endpoint devices 105-107 are configured for communication with the core packet network 110 via an access network 108. The network elements 109 and 111 may serve as gateway servers or edge routers for the network 110.

The endpoint devices 102-107 may comprise customer endpoint devices such as personal computers, laptop computers, Personal Digital Assistants (PDAs), servers, routers, and the like. The access networks 101 and 108 serve as a means to establish a connection between the endpoint devices 102-107 and the NEs 109 and 111 of the IP/MPLS core network 110. The access networks 101 and 108 may each comprise a Digital Subscriber Line (DSL) network, a broadband cable access network, a Local Area Network (LAN), a Wireless Access Network (WAN), and the like.

The access networks 101 and 108 may be either directly connected to NEs 109 and 111 of the IP/MPLS core network 110 or through an Asynchronous Transfer Mode (ATM) and/or Frame Relay (FR) switch network 130. If the connection is through the ATM/FR network 130, the packets from customer endpoint devices 102-104 (traveling towards the IP/MPLS core network 110) traverse the access network 101 and the ATM/FR switch network 130 and reach the border element 109.

The ATM/FR network 130 contains Layer 2 switches functioning as Provider Edge Routers (PER) and/or Provider Routers (PR). The PERs may also contain an additional Route Processing Module (RPM) that converts Layer 2 frames to Layer 3 Internet Protocol (IP) frames. An RPM enables the transfer of packets from a Layer 2 Permanent Virtual Connection (PVC) circuit to an IP network which is connectionless.

Some NEs (e.g., NEs 109 and 111) reside at the edge of the core infrastructure and interface with customer endpoints over various types of access networks. An NE that resides at the edge of a core infrastructure is typically implemented as an edge router, a media gateway, a border element, a firewall, a switch, and the like. An NE may also reside within the network (e.g., NEs 118-120) and may be used as a mail server, honeypot, a router, or like device. The IP/MPLS core network 110 also comprises an application server 112 that contains a database 115. The application server 112 may comprise any server or computer that is well known in the art, and the database 115 may be any type of electronic collection of data that is also well known in the art. Those skilled in the art will realize that although only six endpoint devices, two access networks, and so on are depicted in FIG. 1, the communication system 100 may be expanded by including additional endpoint devices, access networks, border elements, etc. without altering the present invention.

The above IP network is described to provide an illustrative environment in which packets for voice and data services are transmitted on networks. An enterprise customer may build a Virtual Private Network (VPN) by connecting multiple sites or users over a network from a telephony service provider. The enterprise VPN may be managed by the network service provider. When the network service provider manages the VPNs, a Customer Edge Router (CER) located at the customer premise is connected to the network service provider's Layer 2 network through a Provider Edge Router (PER). For example, a VPN site for a customer may have a CER connected to a PER in the service provider's Layer 2 network. The Layer 2 network may be an Asynchronous Transfer Mode (ATM) and/or Frame Relay (FR) network. The customer traffic is then transmitted to the IP/MPLS core network through an ATM/FR switch network. The ATM/FR switch (attached to the IP/MPLS core network) converts the packets from Layer 2 ATM/FR cells to IP packets and forwards the IP packets towards a border element for the IP/MPLS core network. A Permanent Virtual Circuit (PVC) may be established over one or more trunks in the ATM/FR network and may be used for enabling traffic to traverse the ATM/FR network from one switch to another. However, when a customer or a monitoring system reports trouble for the PVC, the service provider may not be able to determine whether or not the reported trouble is due to a port failure/degradation or a PVC failure/degradation. Improper isolation increases the time and cost associated with handling the trouble. A ticket opened for a customer trouble may be inappropriately closed after testing a non-failed network component. Trouble escalation and/or manual intervention add tremendous cost for maintenance of a network and also reduce customer satisfaction with the quality of service. Therefore, there is a need for a method that provides trouble isolation for permanent virtual circuits.

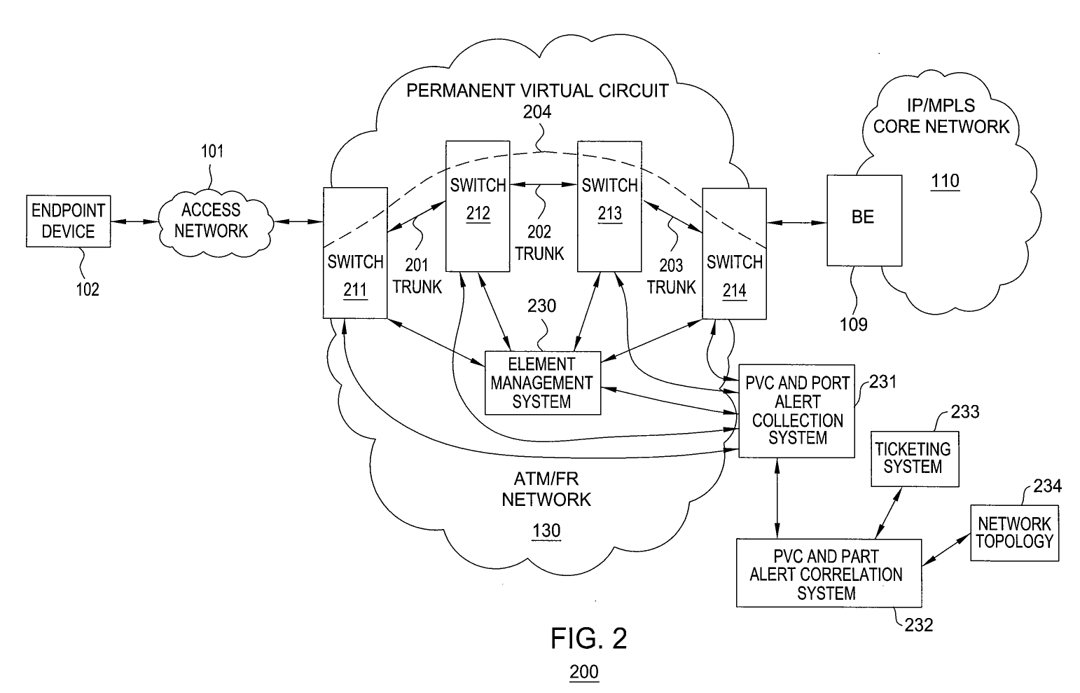

In one embodiment, the current invention provides trouble isolation for permanent virtual circuits. FIG. 2 illustrates an exemplary network 200 with the current invention for trouble isolation for permanent virtual circuits. A customer is using endpoint device 102 to obtain a service from an IP/MPLS core network 110. Traffic between the endpoint device 102 and the IP/MPLS core network 110 traverses the access network 101 and the ATM/FR network 130. The endpoint device 102 is connected to an ATM/FR switch 211 located in the ATM/FR network 130 through access network 101. The ATM/FR network 130 contains ATM/FR switches 211-214. The ATM/FR switch 211 is functioning as a PER for the ATM/FR network 130 for packets originated by customer endpoint device 102. Trunk 201 connects ATM/FR switches 211 and 212. Trunk 202 connects ATM/FR switches 212 and 213. Trunk 203 connects ATM/FR switches 213 and 214. The ATM/FR switch 214 is connected to the IP/MPLS core network 110 through a border element 109. A Permanent Virtual Circuit 204 is established connecting ATM/FR switches 211 and 214 over trunks 201, 202 and 203 for providing a service to the customer endpoint device 102. Traffic from customer endpoint device 102 directed towards IP/MPLS core network 110, traverses the ATM/FR network 130 using the permanent virtual circuit 204. In one embodiment, a PVC and port alert collection system 231 is connected to switches 211-214 directly. In another embodiment, the PVC and port alert collection system is connected to switches 211-214 through an element management system 230. The service provider implements the invention for trouble isolation for a PVC, in a PVC and port alert correlation system 232. The PVC and port alert correlation system 232 is also connected to a ticketing system 233 and a network topology system 234. The service provider stores network topology including an association of PVCs, trunks, ports and switches (nodes) in a network topology system 234. For example, PVC 204 may be associated with various ports on switches 211-214. The service provider configures a time interval for correlation window for port and PVC alerts and/or tickets in the PVC and port alert correlation system 232. For example, one minute, 5 minutes, etc. An alert may be received for an alarm or may be received for a suspected trouble (needing further analysis). For example, a customer may suspect an intermittent trouble for his/her service based on an increased connection time. The trouble may or may not be due a fault. However, an alert may be generated. In another example, an alert may be associated with an alarm. In this case, the alert may be generated due to a network alarm. When an alert or a ticket for a PVC is received, the PVC and port alert correlation system 232 starts the time for correlation window. The PVC and port alert correlation system 232 gathers port and PVC alerts for the duration of said correlation window. If a port down or degraded alert is received along with a PVC down or degraded alert within the correlation window for a port associated with said PVC, the PVC and port alert correlation system 232 reports a port down or degraded alert. If only a PVC down or degraded alert is received within the correlation window, the PVC and port alert correlation system 232 reports a PVC “down” or a PVC “degraded”, accordingly.

In one embodiment, the method also determines whether or not a customer allows intrusive testing. For example, a customer may subscribe to a service that includes trouble isolation among troubles at customer premise, network, etc. and allow the network to perform intrusive testing. For example, if a PVC down/degraded is reported, the service provider may determine whether or not the facility between the CER and PER is “down/degraded.” If the facility between the CER and PER is down or degraded, the service provider may notify the customer of a CPE problem. Otherwise, the service provider may proceed to perform tests on the ATM, PVC, etc. to sectionalize and refer the trouble to an appropriate work center.

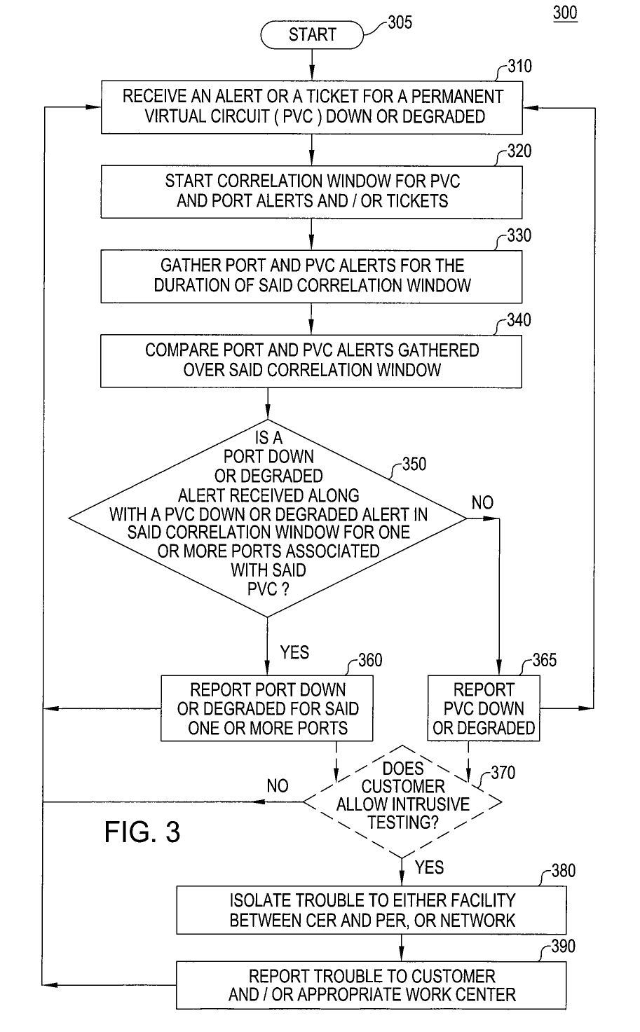

FIG. 3 illustrates a flowchart of a method 300 for trouble isolation for permanent virtual circuits. The service provider implements the invention for trouble isolation for a PVC in a PVC and port alert correlation system. For example, the service provider configures a PVC and port alert correlation time window (e.g. 1 minute), and stores network topology including associations among ports, PVCs, trunks and switches, and so on. Method 300 starts in step 305 and proceeds to step 310.

In step 310, method 300 receives an alert or a ticket for a Permanent Virtual Circuit (PVC) “down” or “degraded.” For example, a customer interacts with a ticketing system and reports that a PVC is down or degraded. In another example, an alert collection system receives an alert for a PVC down.

In step 320, method 300 starts a correlation window for PVC and port alerts and/or tickets. For the example above, the PVC and port alert correlation window of 1 minute may be started. The time window for correlation is configured by the network service provider.

In step 330, method 300 gathers port and PVC alerts for the duration of said correlation window. For the example above, the PVC and port alert correlation system gathers PVC and port alerts for 1 minute for ports associated with said PVC.

In step 340, method 300 compares port and PVC alerts gathered over said correlation window. For the above example, the PVC and port alert correlation system compares the alerts for all ports associated with said PVC for the duration of said correlation window. For example, a port down or degraded alert may be received for one or more ports associated with said PVC in the same correlation time window.

In step 350, method 300 determines whether or not a port down or degraded alert is received along with a PVC down/degraded alert in said correlation window for one or more ports associated with said PVC. If at least one said port down or degraded alert is received, the method proceeds to step 360. Otherwise, the method proceeds to step 365.

In step 360, method 300 reports port down or degraded for said one or more ports. For example, the method may report a port on a switch used to establish the PVC is “down” or “degraded.” The method then proceeds to step 310 to continue receiving PVC down or degraded alerts and/or tickets. In one embodiment, the method also proceeds to step 370 to determine whether or not a customer allows intrusive testing.

In step 365, method 300 reports PVC down or degraded for said PVC. The method then proceeds to step 310 to continue receiving PVC down or degraded alerts and/or tickets. In one embodiment, the method also proceeds to step 370 to determine whether or not a customer allows intrusive testing.

In step 370, method 300 determines whether or not a customer allows intrusive testing. For example, a customer contract may include trouble isolation, diagnosis, and/or repair by performing intrusive testing. If the customer allows intrusive testing, the method proceeds to step 380. Otherwise, the method proceeds to step 310 to continue receiving PVC down or degraded alerts and/or tickets.

In step 380, method 300 isolates trouble to either a trouble on a facility between a Customer Edge Router (CER) and Provider Edge Router (PER) or a trouble on the network portion. The method then proceeds to step 390.

In step 390, method 300 reports trouble to customer and/or appropriate work center. For example, if the trouble is associated with the facility between the CER and PER, the method notifies the customer of trouble at the customer premise. If the trouble is on the network portion, the method may perform other tests to sectionalize the particular network portion and report the failure. For example, physical failures may be reported to one work center while failures associated with network congestion, software, etc. are reported to another work center. The method then proceeds to step 310 to continue receiving PVC down or degraded alerts and/or tickets.

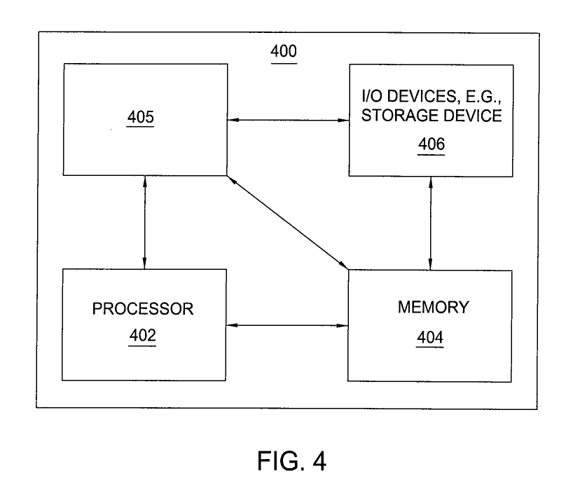

FIG. 4 depicts a high-level block diagram of a general-purpose computer suitable for use in performing the functions described herein. As depicted in FIG. 4, the system 400 comprises a processor element 402 (e.g., a CPU), a memory 404, e.g., random access memory (RAM) and/or read only memory (ROM), a module 405 for providing trouble isolation for a Permanent Virtual Circuit (PVC) on networks, and various input/output devices 406 (e.g., storage devices, including but not limited to, a tape drive, a floppy drive, a hard disk drive or a compact disk drive, a receiver, a transmitter, a speaker, a display, a speech synthesizer, an output port, and a user input device (such as a keyboard, a keypad, a mouse, and the like)).

It should be noted that the present invention can be implemented in software and/or in a combination of software and hardware, e.g., using application specific integrated circuits (ASIC), a general purpose computer or any other hardware equivalents. In one embodiment, the present module or process 405 for providing trouble isolation for a PVC on networks can be loaded into memory 404 and executed by processor 402 to implement the functions as discussed above. As such, the present method 405 for providing trouble isolation for a PVC on networks (including associated data structures) of the present invention can be stored on a computer readable medium or carrier, e.g., RAM memory, magnetic or optical drive or diskette and the like.

While various embodiments have been described above, it should be understood that they have been presented by way of example only, and not limitation. Thus, the breadth and scope of a preferred embodiment should not be limited by any of the above-described exemplary embodiments, but should be defined only in accordance with the following claims and their equivalents.

What is claimed is:

1. A method for providing trouble isolation for a Permanent Virtual Circuit (PVC) comprising:
receiving an alert or a ticket for a Permanent Virtual Circuit (PVC) down or a PVC degraded;
starting a correlation window for said PVC and port alert or ticket;
gathering a plurality of port and PVC alerts for a duration of said correlation window; and
determining whether or not a port down or a port degraded alert is received along with a PVC down or a PVC degraded alert in said correlation window for one or more ports associated with said PVC.

2. The method of claim 1, further comprising:
reporting port down or degraded for said one or more ports if at least one said port down or degraded alert is received; and
reporting PVC down or degraded for said PVC if no port down and no port degraded alert is received along with a PVC down or a PVC degraded alert in said correlation window for said PVC.

3. The method of claim 1, wherein said correlation window is configurable per PVC.

4. The method of claim 1, wherein said correlation window is configurable for a network.

5. The method of claim 1, wherein said PVC is associated with one or more switches.

6. The method of claim 1, wherein said PVC is associated with one or more trunks.

7. The method of claim 1 further comprising:
isolating trouble to either a trouble on a facility between a Customer Edge Router (CER) and a Provider Edge Router (PER), or a trouble on the service provider's network.

8. The method of claim 7, wherein the service provider reports trouble to one or more customers or work centers.

9. A computer-readable medium having stored thereon a plurality of instructions, the plurality of instructions including instructions which, when executed by a processor, cause the processor to perform the steps of a method for providing trouble isolation for a Permanent Virtual Circuit (PVC), comprising:
receiving an alert or a ticket for a Permanent Virtual Circuit (PVC) down or a PVC degraded;
starting a correlation window for said PVC and port alert or ticket;
gathering a plurality of port and PVC alerts for a duration of said correlation window; and
determining whether or not a port down or a port degraded alert is received along with a PVC down or a PVC degraded alert in said correlation window for one or more ports associated with said PVC.

10. The computer-readable medium of claim 9, further comprising:
reporting port down or degraded for said one or more ports if at least one said port down or degraded alert is received; and
reporting PVC down or degraded for said PVC if no port down and no port degraded alert is received along with a PVC down or a PVC degraded alert in said correlation window for said PVC.

11. The computer-readable medium of claim 9, wherein said correlation window is configurable per PVC.

12. The computer-readable medium of claim 9, wherein said correlation window is configurable for a network.

13. The computer-readable medium of claim 9, wherein said PVC is associated with one or more switches.

14. The computer-readable medium of claim 9, wherein said PVC is associated with one or more trunks.

15. The computer-readable medium of claim 9 further comprising:
isolating trouble to either a trouble on a facility between a Customer Edge Router (CER) and a Provider Edge Router (PER), or a trouble on the service provider's network.

16. The computer-readable medium of claim 15, wherein the service provider reports trouble to one or more customers or work centers.

17. An apparatus for providing trouble isolation for a Permanent Virtual Circuit (PVC) comprising:
means for receiving an alert or a ticket for a Permanent Virtual Circuit (PVC) down or a PVC degraded;
means for starting a correlation window for said PVC and port alert or ticket;
means for gathering a plurality of port and PVC alerts for a duration of said correlation window; and
means for determining whether or not a port down or a port degraded alert is received along with a PVC down or a PVC degraded alert in said correlation window for one or more ports associated with said PVC.

18. The apparatus of claim 17, further comprising:
means for reporting port down or degraded for said one or more ports if at least one said port down or degraded alert is received; and
means for reporting PVC down or degraded for said PVC if no port down and no port degraded alert is received along with a PVC down or a PVC degraded alert in said correlation window for said PVC.
